(19) United States
(12) Patent Application Publication
(10) Pub. No.: US 2008/0277146 A1
(43) Pub. Date: Nov. 13, 2008

(54) Radiant heat printed circuit board and method of fabricating the same

(75) Inventors: Yun Seok Hwang, Busan (KR); Cheol Ho Heo, Busan (KR); Geun Ho Kim, Daejeon (KR); Young Ho Lee, Busan (KR); Chan yeup Chung, Daegu (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/010,439

(22) Filed: Jan. 24, 2008

(30) Foreign Application Priority Data
May 7, 2007 (KR) 10-2007-0044101

(51) Int. Cl. H05K 1/03; H05K 3/00

(52) U.S. Cl. 174/255; 427/534

(57) ABSTRACT

Disclosed is a radiant heat printed circuit board, which has improved heat-radiating properties and reliability, and a method of fabricating the same.

### CROSS REFERENCE TO RELATED APPLICATION

This application claims the benefit of Korean Patent Application No. 10-2007-0044101, filed May 7, 2007, entitled “Radiant heat printed circuit board and fabricating method of the same”, which is hereby incorporated by reference in its entirety into this application.

### BACKGROUND OF THE INVENTION

1. Field of the Invention

The present invention relates, in general, to a radiant heat printed circuit board and a method of fabricating the same, and more particularly, to a radiant heat printed circuit board that has improved heat-radiating properties and reliability and to a method of fabricating the same.

2. Description of the Related Art

Generally, a printed circuit board (PCB) has a plurality of conductive patterns designed to comprise a predetermined circuit pattern, and thus, high-temperature heat is generated by the conductive pattern and the mounted or embedded devices.

However, when heat of a predetermined level or more is generated by the mounted or embedded devices, circuit errors, including operational failure or breakage of the circuit, occur. In order to dissipate heat generated by the mounted or embedded devices, a PCB in which an aluminum core is inserted into the center thereof has been proposed.

The PCB, in which the aluminum core is inserted into the center thereof is fabricated through the method shown in FIGS. 1A to 1D.

FIGS. 1A to 1D are sectional views illustrating the process of fabricating the radiant heat PCB according to a conventional technique.

As illustrated in FIG. 1A, prepared is a PCB 100, in which an insulating layer 104, a copper clad laminate (CCL) having inner circuit patterns 112 on both sides thereof, and a single-sided CCL (RCC) having a copper foil 110 on one side thereof are sequentially laminated on each of both surfaces of an aluminum core 102 for dissipating heat generated by the devices mounted on or embedded in the PCB.

After the preparation of the PCB 100, a via hole 114 is formed through the PCB using a CNC drill, as illustrated in FIG. 1B.

The via hole 114 functions to electrically connect the upper portion of the PCB 100 to the lower portion thereof.

After the formation of the via hole 114, deburring is conducted to remove burrs on the copper foil, dust particles on the inner wall of the via hole, dust on the copper foil, and fingerprints, generated upon drilling.

Subsequently, desmearing is conducted to remove smears attached to the inner wall of the via hole caused by melting of the resin constituting the PCB, for example, the insulating layer 104 laminated on both surfaces of the aluminum core 102, the insulating layer 106 of the CCL 106, 112 having the insulating layer 106 and the inner circuit patterns 112 on both sides thereof, and the insulating layer 108 of the RCC 108, 110 having the insulating layer 108 and the copper foil 110 on one side thereof, attributable to heat generated by the drill bit upon drilling.

After the desmearing is conducted, an electroless copper plating layer 116 and a copper electroplating layer 118 are formed on the inner wall of the via hole 114 and the copper foil 110 through electroless copper plating and copper electroplating, as illustrated in FIG. 1C.

After the formation of the electroless copper plating layer 116 and the copper electroplating layer 118, a dry film (not shown) is applied on the copper electroplating layer 118, after which the portion of the dry film, other than the portion of the dry film that covers the portion of the copper electroplating layer corresponding to an outer circuit pattern, is removed through exposure and development.

Subsequently, the portion of the copper electroplating layer 118 from which the dry film is removed, and the electroless copper plating layer 116 and the copper foil 110, corresponding thereto, are removed using an etchant, thus forming the outer circuit pattern 120, as illustrated in FIG. 1D.

After the formation of the outer circuit pattern 120, the dry film remaining on the outer circuit pattern 120 is removed.

However, the method of fabricating the radiant heat PCB according to the conventional technique is disadvantageous because smears are removed using a polishing agent and water or by spraying water into the via hole 114 using a high-pressure washer, and thus the degree of removal thereof is decreased, so that the subsequently formed electroless copper plating layer is not efficiently formed on the inner wall of the via hole, undesirably decreasing the reliability of the PCB.

Further, the method of fabricating the radiant heat PCB according to the conventional technique is disadvantageous because the acid or alkali used in the electroless copper plating melts the aluminum core 102, which is weakly resistant thereto, and thus the electroless copper plating layer is not efficiently formed on the inner wall of the via hole where the aluminum core 102 is located, so that the upper portion of the PCB is not electrically connected to the lower portion thereof, undesirably decreasing the reliability of the PCB.

### SUMMARY OF THE INVENTION

Accordingly, the present invention provides a radiant heat PCB, which has improved heat-radiating properties and reliability, and a method of fabricating the same.

According to the present invention, a radiant heat PCB may include an aluminum core; a plurality of insulating layers laminated on both surfaces of the aluminum core; an inner circuit pattern formed between the insulating layers; an outer circuit pattern formed on the outermost insulating layer; a via hole formed through the aluminum core and the plurality of insulating layers; and a nickel plating layer formed on the aluminum core exposed to the inner wall of the via hole to protect the aluminum core exposed to the inner wall of the via hole.

In addition, a method of fabricating a radiant heat PCB may include a) preparing a PCB, in which a first insulating layer, a CCL having a second insulating layer and inner circuit patterns on both sides thereof, and a single-sided CCL having a third insulating layer and a copper foil on one side thereof are sequentially laminated on each of both surfaces of an aluminum core; b) forming a via hole through the PCB; c) removing smears from the inner wall of the via hole using plasma; d) forming a nickel plating layer on the aluminum core exposed to the inner wall of the via hole; and e) forming an outer circuit pattern on the third insulating layer.

### BRIEF DESCRIPTION OF THE DRAWINGS

FIGS. 1A to 1D are sectional views sequentially illustrating the process of fabricating a radiant heat PCB, according to a conventional technique;

FIG. 2 is a sectional view illustrating the radiant heat PCB, according to the present invention; and

FIGS. 3A to 3E are sectional views sequentially illustrating the process of fabricating a radiant heat PCB, according to the present invention.

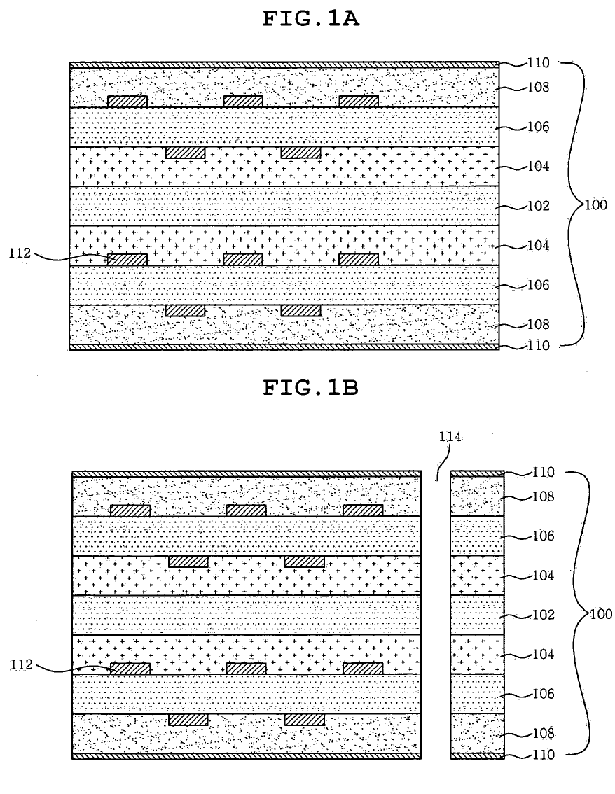

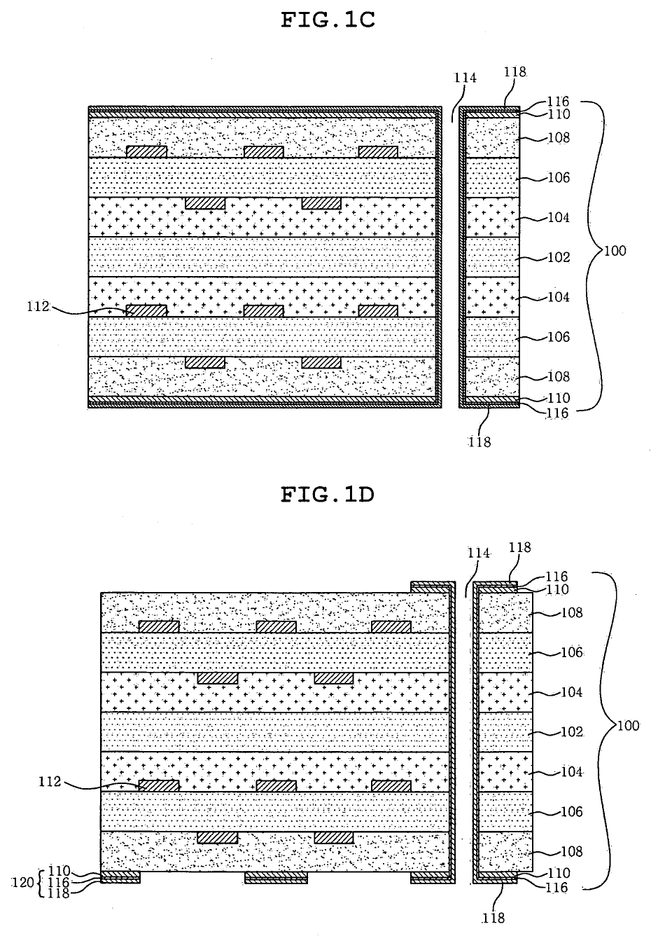

### DESCRIPTION OF THE PREFERRED EMBODIMENTS

Hereinafter, a detailed description will be given of the preferred embodiments of the present invention, with reference to the appended drawings.

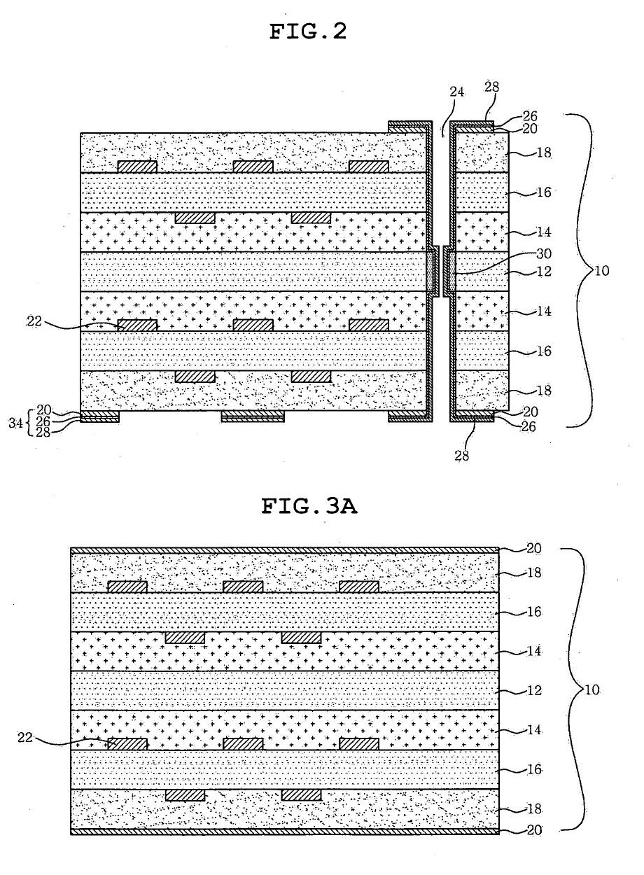

FIG. 2 is a sectional view illustrating the radiant heat PCB, according to the present invention.

With reference to FIG. 2, the radiant heat PCB, according to the present invention, includes an aluminum core 12, first insulating layers 14, second insulating layers 16, third insulating layers 18, inner circuit patterns 22, outer circuit patterns 34, a via hole 24, and a nickel plating layer 30.

The aluminum core 12 is inserted into the center of the PCB to thus dissipate heat generated by the devices mounted on or embedded in the PCB, and is used as a ground.

The first insulating layer 14 is laminated on each of both surfaces of the aluminum core 12 and thus functions to electrically disconnect the aluminum core 12 from the exterior.

The second insulating layer 16 is laminated on the first insulating layer 14, and functions to electrically disconnect the inner circuit patterns 22, formed on both sides thereof, from each other.

Specifically, the second insulating layer 16 electrically disconnects the inner circuit pattern 22 formed thereon from the inner circuit pattern 22 formed thereunder.

The third insulating layer 18 is laminated on the second insulating layer 16, and functions to electrically disconnect the outer circuit pattern 34, formed on the outermost layer of the PCB, from the inner circuit pattern 22.

The via hole 24 is formed through the aluminum core 12, the first insulating layers 14, the second insulating layers 16, and the third insulating layers 18, in order to electrically connect the upper portion of the PCB to the lower portion thereof.

The nickel plating layer 30 is formed on the aluminum core 12 exposed to the inner wall of the via hole 24 so that the aluminum core 12, exposed to the inner wall of the via hole 24, is prevented from being melted when an electroless copper plating layer is formed.

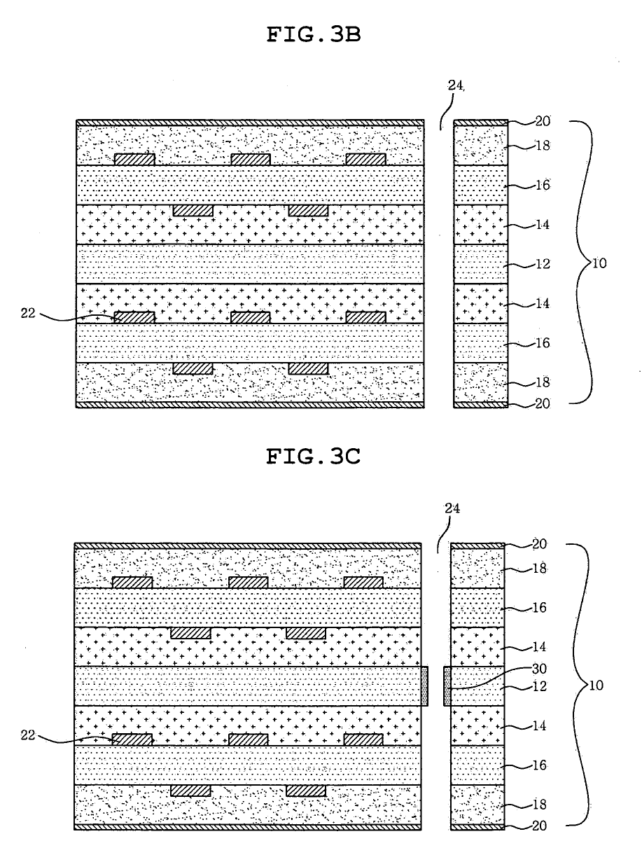

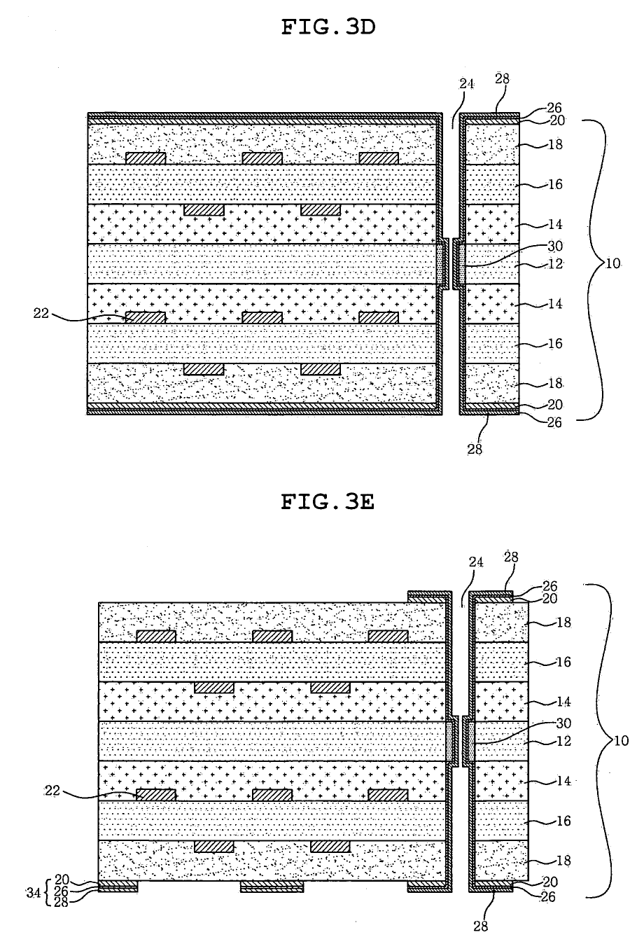

FIGS. 3A to 3E sequentially illustrate the process of fabricating the radiant heat PCB, according to the present invention.

As illustrated in FIG. 3A, prepared is a PCB, in which the fist insulating layer 14, the CCL having the second insulating layer 16 and the inner circuit patterns 22 on both sides thereof, and the single-sided CCL (RCC) having the third insulating layer 18 and the copper foil 20 on one side thereof are sequentially laminated on each of both surfaces of the aluminum core 12.

As the first insulating layer 14, a prepreg is used, and, as the second insulating layer 16 and the third insulating layer 18, FR-4, in which glass fiber is impregnated with epoxy resin, is mainly used.

Here, the PCB 10 may be formed through one of the three methods mentioned below.

The first method follows.

The CCL, including the insulating layer 16 and the copper foils on both sides thereof, is prepared.

Thereafter, a dry film (not shown) is applied on the copper foil of the CCL, after which the portion of the dry film, other than the portion of the dry film that covers the portion of the copper foil corresponding to the inner circuit pattern 22, is removed through exposure and development.

After the removal of the dry film, the portion of the copper foil from which the dry film is removed is etched using an etchant.

Accordingly, the inner circuit pattern 22, which is the portion of the copper foil on which the dry film remains, is formed on both sides of the second insulating layer 16.

After the formation of the inner circuit pattern 22, the dry film remaining on the inner circuit pattern 22 is removed.

Subsequently, the fist insulating layer 14, the CCL having the second insulating layer 16 and the inner circuit patterns 22 on both sides thereof, and the RCC having the third insulating layer 18 and the copper foil on one side thereof are sequentially formed on each of both surfaces of the aluminum core 12, and are then heated and compressed using a press, thus forming the PCB 10.

In addition to the formation of the inner circuit pattern 22 using only the copper foil, the inner circuit pattern 22 may be formed by forming the electroless copper plating layer and the copper electroplating layer on the copper foil and then applying the dry film.

Specifically, the second method of forming the PCB 10 includes forming the electroless copper plating layer and the copper electroplating layer on the copper foil laminated on both sides of the second insulating layer 16 and then applying the dry film on the copper electroplating layer.

The subsequent procedure is conducted in the same manner as in the first method, including applying the dry film on the copper foil to form the inner circuit pattern 22, thus forming the inner circuit pattern 22. After the formation of the inner circuit pattern 22, the fist insulating layer 14, the CCL having the second insulating layer 16 and the inner circuit patterns 22 on both sides thereof, and the RCC having the third insulating layer 18 and the copper foil 20 on one side thereof are sequentially formed on each of both surfaces of the aluminum core 12, and are then heated and compressed using a press, thereby forming the PCB 10.

In addition, the inner circuit pattern 22 may be formed by forming the electroless copper plating layer and the copper electroplating layer on both sides of the second insulating layer 16 and then applying the dry film.

Specifically, the third method of forming the PCB 10 includes forming the electroless copper plating layer and the copper electroplating layer on both sides of the second insulating layer 16 and then applying the dry film on the copper electroplating layer.

The subsequent procedure is conducted in the same manner as in as the first method, including applying the dry film on the copper foil to form the inner circuit pattern 22, thus forming the inner circuit pattern 22. After the formation of the inner circuit pattern 22, the fist insulating layer 14, the CCL having the second insulating layer 16 and the inner circuit patterns 22 on both sides thereof, and the RCC having the third insulating layer 18 and the copper foil 20 on one side thereof are sequentially formed on each of both surfaces of the aluminum core 12, and are then heated and compressed using a press, thereby forming the PCB 10.

Alternatively, the PCB 10 may be formed by sequentially forming, on each of both surfaces of the aluminum core 12, the fist insulating layer 14, the CCL having the second insulating layer 16 and the inner circuit patterns 22 on both sides thereof, the third insulating layer 18, and the copper foil 20, and then heating and compressing them using a press.

After the preparation of the PCB 10, the via hole 24 is formed through the PCB 10 using a CNC drill, as illustrated in FIG. 3B.

The via hole 24 plays a role in electrically connecting the upper portion of the PCB 10 to the lower portion thereof.

After the formation of the via hole 24, deburring is conducted to remove burrs on the copper foil, dust particles on the inner wall of the via hole, dust on the copper foil, and fingerprints, generated upon drilling.

Thereafter, smears attached to the inner wall of the via hole 24 caused by melting of the resin constituting the PCB, for example, the first insulating layer 14, the second insulating layer 16, and the third insulating layer 18, attributable to heat generated by the drill bit upon drilling, are removed using plasma, composed of nitrogen, CF4 and oxygen.

Because plasma decomposes and removes the smears, the smears attached to the inner wall of the via hole 24 are completely removed using plasma.

After the removal of the smears, the nickel plating layer 30 is formed on the aluminum core 12 exposed to the inner wall of the via hole 24 through plating, as illustrated in FIG. 3C.

The nickel plating layer 30 functions to prevent the aluminum core 12 from being melted by the acid or alkali subsequently used in electroless copper plating.

After the formation of the nickel plating layer 30, the electroless copper plating and the copper electroplating are sequentially conducted, thus forming the electroless copper plating layer 26 and the copper electroplating layer 28 on the inner wall of the via hole 24 and the copper foil 20, as illustrated in FIG. 3D.

After the formation of the electroless copper plating layer 26 and the copper electroplating layer 28, a dry film (not shown) is applied on the copper electroplating layer 28, after which the portion of the dry film, other than the portion of the dry film covering the portion of the copper electroplating layer corresponding to an outer circuit pattern, is removed through exposure and development.

Subsequently, the portion of the copper electroplating layer 28 from which the dry film is removed, and the electroless copper plating layer 26 and the copper foil 20, corresponding thereto, are removed using an etchant, thus forming the outer circuit pattern 34, as illustrated in FIG. 3E.

After the formation of the outer circuit pattern 34, the dry film remaining on the outer circuit pattern 34 is removed.

In the radiant heat PCB and the method of fabricating the same according to the present invention, after the formation of the via hole 24, the smears attached to the inner wall of the via hole 24 are decomposed and removed using plasma, thereby completely removing them. Hence, the subsequent electroless copper plating layer is efficiently formed, consequently increasing the reliability of the PCB.

In the radiant heat PCB and the method of fabricating the same according to the present invention, after the formation of the via hole 24, the nickel plating layer 30 is formed on the aluminum core 12 exposed to the inner wall of the via hole 24, thereby preventing the aluminum core 12 from being melted by the acid or alkali subsequently used in electroless copper plating, so that the electroless copper plating layer 26 and the copper electroplating layer 28 are uniformly formed on the inner wall of the via hole 24, consequently increasing the reliability of the PCB.

In the radiant heat PCB and the method of fabricating the same according to the present invention, because the aluminum core 12 is inserted into the center of the PCB, heat generated by the mounted or embedded devices is dispersed into the aluminum core 12, thus improving heat-radiating properties.

As described hereinbefore, the present invention provides a radiant heat PCB and a method of fabricating the same. According to the present invention, after a via hole is formed, smears attached to the via hole can be completely removed through decomposition and removal using plasma, so that a subsequent electroless copper plating layer can be efficiently formed, consequently increasing the reliability of the PCB.

Further, after the formation of the via hole, a nickel plating layer is formed on the aluminum core exposed to the inner wall of the via hole, thus preventing the melting of the aluminum core attributable to an acid or alkali subsequently used in electroless copper plating, so that the electroless copper plating layer and the copper electroplating layer can be uniformly formed on the inner wall of the via hole, consequently increasing the reliability of the PCB.

Furthermore, because the aluminum core is inserted into the center of the PCB, heat generated by the mounted or embedded device is dispersed in the aluminum core, thus improving heat-radiating properties.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A radiant heat printed circuit board, comprising:
an aluminum core;
a plurality of insulating layers laminated on both surfaces of the aluminum core;
an inner circuit pattern formed between the insulating layers;
an outer circuit pattern formed on the outermost insulating layer;
a via hole formed through the aluminum core and the plurality of insulating layers; and
a nickel plating layer formed on the aluminum core exposed to an inner wall of the via hole to protect the aluminum core exposed to the inner wall of the via hole.

2. A method of fabricating a radiant heat printed circuit board, comprising:
a) preparing a printed circuit board, in which a first insulating layer, a copper clad laminate having a second insulating layer and inner circuit patterns on both sides thereof, and a single-sided copper clad laminate having a third insulating layer and a copper foil on one side thereof are sequentially laminated on each of both surfaces of an aluminum core;
b) forming a via hole through the printed circuit board;
c) removing smears from an inner wall of the via hole using plasma;
d) forming a nickel plating layer on the aluminum core exposed to the inner wall of the via hole; and
e) forming an outer circuit pattern on the third insulating layer.

3. The method as set forth in claim 2, wherein the a) preparing the printed circuit board comprises:
a-1) preparing the copper clad laminate having the second insulating layer and copper foils on both sides thereof;
a-2) applying a dry film on the copper foil of the copper clad laminate, and then removing a portion of the dry film, other than a portion of the dry film covering a portion of the copper foil corresponding to the inner circuit pattern, through exposure and development;
a-3) removing the portion of the copper foil from which the dry film is removed, using an etchant, thus forming the inner circuit pattern;
a-4) removing the dry film remaining on the inner circuit pattern; and
a-5) sequentially forming, on the aluminum core, the first insulating layer, the copper clad laminate having the second insulating layer and the inner circuit patterns on both sides thereof, and the single-sided copper clad laminate having the third insulating layer and the copper foil on one side thereof, and then heating and compressing them using a press.

4. The method as set forth in claim 2, wherein the first insulating layer is a prepreg, and the second insulating layer and the third insulating layer are FR-4.

5. The method as set forth in claim 2, wherein the plasma comprises nitrogen, CF4, and oxygen.
